(19) United States
(12) Patent Application Publication
(10) Pub. No.: US 2024/0159593 A1
(43) Pub. Date: May 16, 2024

(54) OPTOELECTRONIC DEVICE AND METHOD FOR A SPECTRALLY SELECTIVE DETECTION OF ELECTROMAGNETIC RADIATION

(71) Applicant: SENORICS GMBH, Dresden (DE)

(72) Inventors: Jonas KUBLITSKI, Dresden (DE); Axel FISCHER, Dresden (DE); Donato SPOLTORE, Dresden (DE); Karl LEO, Dresden (DE); Yazhong WANG, Dresden (DE); Louis Conrad WINKLER, Dresden (DE); Johannes BENDUHN, Dresden (DE)

(73) Assignee: SENORICS GMBH, Dresden (DE)

(21) Appl. No.: 18/549,834

(22) PCT Filed: Mar. 11, 2022
(86) PCT No.: PCT/EP2022/056338

§ 371 Date: Sep. 8, 2023

(30) Foreign Application Priority Data
Mar. 12, 2021 (DE) 10 2021 106 049.4

(51) Int. Cl. G01J 5/10

(52) U.S. Cl. CPC G01J 5/10

(57) ABSTRACT

By directly exciting optical transitions to the intermolecular CT state, the wavelength range which can be detected by organic photodetectors can be expanded into the NIR or IR region, wherein, however, the EQE is low even when using resonance effects by arranging the photoactive layer in an optical microcavity. The invention relates to an optoelectronic component (1, 1′, 1″, 1′″) and to a corresponding detection method in which the concentration of the donor compound in the photoactive layer (2) or the concentration of the acceptor compound in the photoactive layer (2) is so low that the low-concentration compound provides trap states for the corresponding charge carriers (81), said trap states causing a photo-induced accumulation of the charge carriers (81) associated with the low-concentration compound in a region of the photoactive layer (2) facing the first electrode (31) so that charge carriers (82) associated with the high-concentration compound are injected into the photoactive layer (2) from the first electrode (31), as a result of which this charge carrier species (82) predominates in the component (1, 1′, 1″, 1′″). The increase in EQE achieved by means of the invention offers the particular advantage of extending the detectable wavelength range to higher wavelengths.

The invention relates to an optoelectronic component for spectrally selective detection of electromagnetic radiation, comprising first and second electrodes which are spaced apart from each other and to which an electrical voltage can be applied, and comprising a photoactive layer comprising a mixed layer containing a donor compound and an acceptor compound, wherein the energy equivalent of a wavelength of electromagnetic radiation to be detected corresponds to the energy to be expended for direct excitation of an intermolecular charge transfer state at an interface between said donor compound and said acceptor compound, said photoactive layer being disposed in an optical microcavity which is arranged between the first and second electrodes and which is constituted of two spaced-apart mirror surfaces, the spacing of the mirror surfaces being such that a standing wave is generated in the microcavity for an incident wave of the electromagnetic radiation having the wavelength to be detected, as well as the associated method.

Optoelectronic components in the form of highly sensitive and fast photodetectors are in demand to meet measurement requirements as in e.g., intelligent vehicles or devices. Photodetectors for the spectrally selective detection of an electromagnetic wave are optoelectronic components which are used for the qualitative and quantitative detection of electromagnetic waves with predefined, specific wavelengths or photons with predefined, specific energies, whereby the waves irradiating the photodetector, referred to as “incident” in the following, generally have a large number of different wavelengths or the incident photons generally have a large number of different energies.

In the following, no distinction is made between the wave picture and the photon picture of electromagnetic radiation, and the associated terms are used essentially synonymously.

A photodetector has a photoactive layer in which electromagnetic radiation is converted into pairs of charge carriers, the charge carriers being negatively charged electrons and positively charged defect electrons or holes. Organic photodetectors typically have a photoactive layer containing an electron donor compound (donor compound or donor, D for short), i.e., a material that donates electrons and accepts defect electrons or holes, and an electron acceptor compound (acceptor compound or acceptor, A for short), i.e., a material that accepts electrons. The separation of the pairs of charge carriers necessary to generate an electrical signal can occur at the interface between the donor and acceptor. After the separation of a charge carrier pair, the holes in the donor and the electrons in the acceptor are transported to the electrodes. In this sense, the holes are understood in the following as the charge carriers assigned to the donor compound and the electrons as the charge carriers assigned to the acceptor compound.

Using the photomultiplication effect to improve the external quantum efficiency (EQE) of a photodetector is one of the most important approaches to achieving high-sensitivity photodetection. EQE refers to the wavelength-dependent ratio of the number of incident photons and charge carriers extracted from the device. It can be understood as a kind of wavelength-dependent efficiency.

Of special interest for many measurement tasks is the near-infrared wavelength range (NIR range) between approx. 780 and 3000 nm, which particularly excites molecular vibrations.

The mode of operation of inorganic avalanche photodiodes used as highly sensitive photodetectors, e.g. Si-based in the NIR range for wavelengths up to approx. 1000 nm or InGaAs-based in the NIR range for wavelengths from approx. 1000 to 1700 nm, is based on the fact that the space charge distribution is shaped by an additional highly p- or n-doped layer in such a way that a region of high field strength can be generated by means of a large voltage in the reverse direction, which acts as a multiplication zone for the charge carriers generated by irradiation. These are accelerated in the multiplication zone so that impact ionization of the crystal lattice takes place, resulting in internal signal amplification.

The photomultiplication (PM) effect can also be exploited in organic photodetectors (OPD), so that PM-OPD can be used to amplify small photocurrents without additional external circuit components. However, the PM effect here is based on increased injection of a first type of charge carrier, i.e., electrons or holes (defect electrons), favored by an energy band bending resulting from accumulation of the opposite, second type of charge carrier, i.e., holes or electrons, near the injecting electrode. The electric field caused by the accumulated second charge carrier species in the vicinity of the injecting electrode bends the relevant energy bands in such a way that the tunneling probability of the first charge carrier species through the injection barrier and/or the conductivity for the first charge carrier species increases sharply. Accumulation of the second charge carrier species may be due to, for example, lack of percolation paths for this charge carrier species and/or trap states for this charge carrier species. An overview of the state of the art regarding organic PM-OPD is provided respectively by Shi, L., et al. Recent Progress in Photomultiplication Type Organic Photodetectors. Nanomaterials 2018, 8, 713, and Miao, J., et al. Recent Progress on Photomultiplication Type Organic Photodetectors. Laser & Photonics Rev. 2019, 13, 1800204.

CN 1 09 935 699 A shows an organic PM-OPD the layer structure of which comprises a transparent substrate, an anode, an anode modification layer, a photoactive layer and a cathode. The photoactive layer is a mixed layer containing a donor compound, e.g., P3HT, PBDB-T, or PDPP3T, and an acceptor compound, e.g., PCBM. A range between 1:100 and 1:5 is given for the donor:acceptor mixing ratio. The anode modification layer is a hole transport or electron blocking layer (HTL or EBL), e.g., of PVK, poly-TPD, ZnO, or PEDOT:PSS. The described PM-OPD is suitable for a wavelength range between 300 and 800 nm.

To advance into the NIR wavelength range, approaches such as that disclosed in CN 1 08 807 683 A exist. In the PM-OPD described therein, the photoactive layer contains an acceptor compound, e.g., PCBM, in which a thin film of a donor compound absorbing in the NIR range up to about 900 nm is embedded. In this case, the optical excitation of the donor by absorption of a photon is accompanied by the formation of a Frenkel exciton, i.e., a strongly localized bound pair of charge carriers.

On the other hand, an extension of the detectable spectral range can be achieved by using the absorption of a photon under direct excitation of an intermolecular charge transfer (CT) state at an interface between a donor and an acceptor compound. The donor and acceptor compounds do not necessarily have to absorb in the NIR region by themselves, i.e., the band gap between the highest occupied orbital (HOMO) and the lowest unoccupied orbital (LUMO) of both the donor and acceptor compounds do not necessarily have to correspond to an energy equivalent lying in the NIR region. Rather, the energy of a photon that can be absorbed via the CT state essentially corresponds to the difference between the higher-energy HOMO of one compound and the lower-energy LUMO of the other compound. In a mixed layer of a donor compound and an acceptor compound, lower-energy photons, i.e., photons with longer wavelengths, are absorbed at the interfaces between one molecule of the donor compound and one molecule of the acceptor compound, respectively, than by one molecule of the donor compound or by one molecule of the acceptor compound. Typically, the energy E_{CT} that can be absorbed via the CT state can also be somewhat lower than the above-mentioned difference between the higher-energy HOMO of one compound and the lower-energy LUMO of the other compound, since the charge carriers associated with each compound attract each other at the interface and are thus slightly more strongly bound. Furthermore, it is observed that intermolecular CT states can generally also absorb photons that have an energy lower than the difference mentioned above. However, for these transitions in particular, the absorption cross section is so small that conventional devices have not yet addressed their use. For an overview of the physics of intermolecular CT states, see, e.g., Vandewal, K. Interfacial Charge Transfer States in Condensed Phase Systems. Annual Review of Physical Chemistry 2016, 67, 113-133.

EP 3 152 785 B1 discloses an OPD in which intermolecular CT states can be exploited for the detection of electromagnetic waves with wavelengths in the NIR or IR range (CT-OPD). In the CT-OPD, the photoactive mixed layer of a donor and an acceptor compound is sandwiched between two mirror surfaces, e.g., two electrodes with reflective surfaces facing each other, forming an optical microcavity. A complex sequence of material layers, hereinafter referred to as “layer structure”, may be arranged in the microcavity of the CT-OPD, wherein, in addition to the photoactive layer, the thickness of which may be, for example, 50 nm, the layer structure may comprise, for example, filter layers for specific wavelength ranges, charge carrier transport layers, charge carrier blocking layers, optically transparent spacer layers, etc.

For electromagnetic waves with a wavelength that satisfies the resonance condition of the optical microcavity, standing waves are formed in the microcavity. The EQE of the CT-OPD is narrowband and significantly increased for such a wavelength. Typically, the resonance condition of an optical cavity formed as a Fabry-Perot cavity is satisfied if the following holds for its optical length n·L:

n·L=(i·λᵢ·cos α)/2,
where n is the effective refractive index over the physical length L of the cavity, which, neglecting the penetration depth of the electromagnetic field into the material having the mirror surfaces, corresponds to the distance of the mirror surfaces from each other, i is the order of the forming standing wave, λᵢ is the wavelength of the incident wave, and α is the angle of incidence of the incident wave with respect to a direction parallel to the physical length L of the cavity. When the cavity is irradiated parallel to the physical length L (α=0), the resonance condition is satisfied if the optical length of the cavity is an integer multiple of half the wavelength of the incident wave.

In reality, incident waves with wavelengths that are in a range around the wavelength for which the above-mentioned resonance condition applies are amplified by the cavity. Thus, compared with a layered structure corresponding to the layered structure of the CT-OPD, which is not located in a microcavity, the EQE of the CT-OPD is increased when the optical path length between the mirror surfaces of the microcavity is 25% to 75% of the wavelength of the incident wave. In the following, the term “resonant wave” is used for those waves where resonance effects occur in the microcavity. Advantageously, the wavelengths for which resonance occurs can be varied by varying the distance between the mirror surfaces.

However, despite the significant increase in EQE by embedding the photoactive mixed layer in a microcavity, the EQE of the CT-OPD is still low compared to the EQE of OPDs that exploit the intramolecular excitation of the donor or the acceptor via its band gap per se. Furthermore, for many measurement tasks, an extension of the detectable wavelength range towards longer wavelengths is desirable.

It is therefore the object of the invention to overcome the disadvantages of the prior art and to provide an optoelectronic component and an associated method which are particularly well suited for the detection of electromagnetic radiation (electromagnetic waves) having wavelengths in the NIR range.

The object is achieved by an optoelectronic component for spectrally selective detection of electromagnetic radiation and an associated method according to the independent claims. Advantageous implementations and embodiments are given in dependent claims.

According to the invention the optoelectronic component for spectrally selective detection of electromagnetic radiation comprises at least:
a first and a second electrode which are spaced apart from one another and to which an electrical voltage can be applied,
a photoactive layer comprising a mixed layer containing a donor compound and an acceptor compound, wherein the energy equivalent of a wavelength of electromagnetic radiation to be detected corresponds to the energy to be expended for direct excitation of an intermolecular charge transfer state at an interface between the donor compound and the acceptor compound,
wherein the photoactive layer is disposed in an optical microcavity, which is arranged between the first and the second electrode and is constituted of two mirror surfaces spaced apart from each other, the distance of the mirror surfaces from each other being such that a standing wave is generated in the microcavity for an incident wave of the electromagnetic radiation having the wavelength to be detected,
wherein the concentration of the donor compound at least in a region of the photoactive layer facing the first electrode or the concentration of the acceptor compound at least in a region of the photoactive layer facing the first electrode is so low that the low-concentration compound provides trap states for the charge carriers assigned to it, which cause a photoinduced accumulation of charge carriers associated with the low-concentration compound in the region of the photoactive layer facing the first electrode, so that charge carriers associated with the high-concentration compound are injected from the first electrode into the photoactive layer, as a result of which this charge carrier species predominates in the device. These charge carriers associated with the highly concentrated compound are transported to the second electrode.

The charge carriers associated with the high-concentration compound are referred to below as “main charge carriers”; the charge carriers associated with the low-concentration compound are referred to as “non-main charge carriers”. If, for example, the photoactive layer is formed in such a way that the concentration of the acceptor molecules is low in the sense described above, holes are the main charge carriers and electrons are the non-main charge carriers.

The optoelectronic component according to the invention can be described as spectrally selective in that, due to the arrangement of the photoactive layer in the microcavity, the EQE is particularly amplified for those incident waves which are resonant waves. The wavelength of the resonant waves can be predetermined by choosing the distance of the mirror surfaces from each other. In this case, the distance of the mirror surfaces from each other is adjusted so that the resonance condition is fulfilled for a certain wavelength λ*. This wavelength λ* is referred to as the “wavelength to be detected”. As explained above, ultimately the EQE is increased in a wavelength range around the wavelength to be detected. The energy equivalent of the wavelength to be detected corresponds to the energy of a photon absorbed under direct excitation of an intermolecular CT state at an interface between donor compound and acceptor compound in the photoactive layer.

The incident waves can be emitted by an illumination system associated with the optoelectronic component according to the invention.

A mirror surface may be a mirror-like surface of an electrode. Preferably, the microcavity is constituted by the spaced, opposing surfaces of the two electrodes of the optoelectronic component, in which case said surfaces of the two electrodes are of mirror-like design. The mirror surfaces have a high reflectivity at least for the wavelength to be detected.

Preferably, the mirror surfaces facing each other are arranged plane-parallel to each other.

The first and second electrodes of the optoelectronic component, one of the two electrodes acting as the cathode and the other of the two electrodes acting as the anode, are configured such that a DC electrical voltage can be applied between them. The voltage is thereby preferably directed such that the non-main charge carriers accumulate in a region of the photoactive layer facing the first electrode and are substantially not injected into the photoactive layer, while the main charge carriers are injected from the first electrode into the photoactive layer. Preferably, the positive pole of the voltage is to be applied to a first electrode acting as a cathode, so that holes are injected into the photoactive layer from the cathode as main charge carriers, while the negative pole is to be applied to the second electrode then acting as an anode. Such a voltage with preferred polarity is referred to in the following as “reverse voltage” or “reverse bias voltage”.

One of the two electrodes can be designed in such a way that illumination of the optoelectronic component can take place through this electrode. For example, the second electrode can be transparent at least for the wavelength to be detected. If the electrode through which illumination is to be performed has a mirror-like surface that represents a mirror surface of the microcavity, the electrode may be partially transparent at least for the wavelength to be detected, so that at least the wavelength to be detected can be transmitted through the electrode, but also reflected by the mirror-like surface of the electrode.

An optoelectronic component according to the invention can be connected to a readout unit for reading out, preferably also for further processing of, electrical signals generated by the optoelectronic component.

At least one of the electrodes can be formed in multiple pieces, i.e., from electrode segments arranged in an array. Different electrode segments can be assigned to different wavelengths to be detected. The readout of the electrical signals is then expediently carried out in such a way that the electrical signals that can be picked up by different electrode segments can be discriminated, e.g., by each electrode segment being connected to a separate readout unit.

The photoactive layer of the optoelectronic component according to the invention comprises a mixed layer in which a donor compound (D) and an acceptor compound (A) are mixed (often referred to as “D:A blend” in the literature). The mixed layer constitutes a bulk heterojunction.

At the interface between a molecule of the donor compound and a molecule of the acceptor compound, photoinduced direct excitation of an intermolecular CT state (also referred to as an “interchromophoric” CT state) can occur. In contrast to the excitation of donor or acceptor by absorption of a photon with energies greater than or equal to the energy gap between HOMO and LUMO of the respective compound, the intermolecular CT state is already excited by a photon with an energy essentially equal to, or even lower than, the energy difference between the highest HOMO and the lowest LUMO of the D:A material combination.

For the known CT-OPD, a volume ratio D:A is preferably chosen for the mixed layer, where the interface between the two compounds in the mixed layer is maximal. For the typical material combination ZnPc:C60, this is the case at a volume ratio of 1:1 or a mass fraction of 50% for both the donor and the acceptor compound, based on the total mass of the mixed layer.

Surprisingly, however, a volume ratio D:A that is significantly different from 1:1 proves to be advantageous in the optoelectronic component according to the invention. In this case, either the concentration or the mass fraction of the acceptor compound at least in a region of the mixed layer facing the first electrode is so low that the acceptor molecules act as electron traps, or the concentration or the mass fraction of the donor compound in at least one region of the mixed layer facing the first electrode is so low that the donor molecules act as hole traps. In this context, a “trap” or “trap state” refers to a location or energetic state that restricts the movement of a charge carrier through the solid.

The effect resulting from the low concentration of one of the compounds of the mixed layer is explained below using the example of a low concentration of the acceptor compound. The skilled person can readily apply the explanation to an embodiment of the device according to the invention with a low concentration of the donor compound.

The reason for the low-concentration acceptor molecules acting as electron traps is the energetic difference of the LUMO of the acceptor to the LUMO of the donor, wherein the LUMO of the acceptor is energetically lower than the LUMO of the donor. Due to the low concentration of the acceptor compound, at least in the near-cathode region of the mixed layer, there are correspondingly very few percolation paths for electrons. If the optoelectronic component is illuminated so that charge carrier pairs are formed, due to photoinduced excitation of CT states, an accumulation of electrons occurs in the near-cathode region of the mixed layer when a reverse voltage is applied between the cathode and anode. The electric field resulting from the increased charge density causes a bending of the energy bands in the region of the mixed layer near the cathode, which leads to the opposite charge carriers, in this case the holes, being able to tunnel from the cathode through the injection barrier. Holes are thus injected from the cathode into the donor phase of the mixed layer, so that the number of holes in the device exceeds the number of electrons. Together with the photoinduced holes, the injected holes are then transported to the anode.

That such a low concentration of one of the compounds of the mixed layer also proves beneficial in a CT-OPD is surprising in that the aforementioned low concentration required for the PM effect reduces the number of CT states, creating a trade-off between increased EQE due to the PM effect at low concentration and increased absorption due to a larger number of CT states at higher concentration (maximizing the contact area of donor and acceptor).

In order to exploit the described advantageous effect in the optoelectronic component according to the invention, it is sufficient in principle if a region of the photoactive layer facing the first electrode, e.g., the cathode, has a sufficiently low concentration of a compound, e.g., the acceptor compound. For the purposes of this description, the region of the photoactive layer facing the first electrode is the region of the photoactive layer that is adjacent to the first electrode, although this can also be indirect, for example via one or more layers arranged between the photoactive layer and the first electrode.

Thus, the entire photoactive layer need not necessarily have such a low concentration of the compound in question. The region facing the first electrode may have a thickness, i.e., an extension substantially perpendicular to the surface of the first electrode, that is significantly less than the thickness of the photoactive layer, e.g., at most 10% of the thickness of the photoactive layer. Typically, the thickness of the region facing the first electrode may be between 5 and 10 nm. The concentration of the low-concentration compound may increase from the region facing the first electrode in a direction facing the surface of the second electrode in the photoactive layer, e.g., until a volume ratio D:A is reached at which the interface between the two compounds in the photoactive layer is maximum, in order to increase the absorption cross-section for direct excitation of intermolecular CT states. Preferably, the photoactive layer has a volume ratio D:A in a region in which the standing wave forming for the wavelength to be detected in the optical microcavity of the optoelectronic component according to the invention has a spatial intensity maximum, at which the absorption cross section for the direct excitation of intermolecular CT states is as high as possible, and particularly preferably is maximum.

The increase in the concentration of the low-concentration compound from a region of the photoactive layer facing the first electrode at least to a region of the photoactive layer different from the region facing the first electrode and closer than the region facing the first electrode to the second electrode may be continuous, e.g., linear, or discontinuous, e.g., step-like, in any manner. However, the entire photoactive layer can also be implemented with the low concentration of one of the compounds according to the invention, i.e., such that the concentration of the donor compound or the concentration of the acceptor compound is so low that the low-concentration compound provides trap states for the charge carriers assigned to it.

The optoelectronic component according to the invention is the first CT-OPD with exploitation of the PM effect. The optoelectronic component according to the invention shows that, unexpectedly, even the generation of very few charge carriers, as is the case here due to the small absorption cross-section of the CT states, is sufficient to trigger the PM effect.

To achieve an amplification effect by arranging the photoactive layer in a microcavity, it is beneficial if the optical losses in the photoactive layer are small enough to allow constructive interference of the waves reflected between the mirror surfaces. Enhancement can thus be expected, especially for optical transitions with small absorption cross-sections, such as the CT transition. An excessive increase in EQE due to the PM effect in this sense may therefore have a negative impact on the detection behavior of a CT-OPD under certain circumstances. An objective of exploiting the PM effect in the optoelectronic component according to the invention is therefore not primarily to increase the EQE above 100%. Rather, the EQE can advantageously be increased in wavelength ranges with intrinsically particularly small EQE. The detection range of the device according to the invention can thus be extended to higher wavelengths at which the EQE was too small in known CT-OPD to trigger a detectable signal. The optoelectronic component according to the invention can thus advantageously extend the wavelength range of the electromagnetic radiation detectable by means of the component to higher wavelengths while keeping the EQE essentially constant.

By suitably increasing the reverse voltage between the cathode and anode, i.e., first and second electrode, of the optoelectronic component, the EQE of the optoelectronic component can be increased.

If no voltage is applied between the first and second electrodes of the optoelectronic component, no PM effect is observed.

Particularly advantageously, the low concentration of one of the compounds of the mixed layer necessary to exploit the PM effect in the optoelectronic component of the invention can be controlled in vacuum-processed small molecule layers. The same applies to an optionally present concentration gradient in the photoactive layer.

Various combinations of donor and acceptor compounds are suitable for the photoactive mixed layer of an optoelectronic component according to the invention. A typical combination is, for example, ZnPc (zinc(II) phthalocyanine) as the donor compound and C₆₀ as the acceptor compound. Here, for example, C₆₀ may be concentrated in the mixed layer at such a low level that the C₆₀ molecules provide trap states for electrons that cause photoinduced accumulation of electrons in a region of the mixed layer facing the cathode, so that holes are injected from the cathode into the mixed layer, resulting in a predominance of holes as charge carriers over electrons in the device.

Other typical D:A combinations that are particularly suitable for the photoactive layer of the optoelectronic component according to the invention are given below as a non-exhaustive list: TPDP:C₆₀; MeO-TPD:C₆₀; m-MTDATA:C₆₀; Pentacene:C₆₀; TAPC:C₆₀; ZnPc:HATNA-Cl₆; TPDP: HATNA-Cl₆; MeO-TPD: HATNA-Cl₆; m-MTDATA: HATNA-Cl₆; Pentacene: HATNA-Cl₆; TAPC: HATNA-Cl₆.

In one embodiment of the optoelectronic component according to the invention, the concentration of the donor compound in the mixed layer or the concentration of the acceptor compound at least in the region of the mixed layer facing the first electrode is between 0.1 and 10% by weight (wt %), which means that the mass fraction of the low-concentration compound in this region of the mixed layer, based on the total mass of the mixed layer in this region, is between 0.1 and 10%, the boundaries included in each case. Preferably, said mass fraction is at least 1 wt % and/or at most 5 wt %. Particularly preferred is a mass fraction of at most 4 wt %, very particularly preferred of at most 3 wt %, the limits in each case included.

For example, in the case of a mixed layer containing ZnPc as the donor compound and C₆₀ as the acceptor compound, a concentration of C₆₀ of 3% by weight has proved to be particularly advantageous in that both the EQE and the specific detectivity of a device comprising the said mixed layer are at a maximum, at least at the wavelength to be detected, compared with devices having a mixed layer of the composition ZnPc:C₆₀ with lower and higher concentrations of C₆₀ (varied in integer steps). The specific detectivity can be understood as a normalized signal-to-noise ratio, taking into account, in a manner known to the skilled person, not only the EQE but also, for example, the dark current of the device.

By exploiting the PM effect, the EQE of an optoelectronic component according to the invention, in particular with a concentration ratio optimized in the above sense, is significantly increased, e.g. by a factor of between 10 and 100, even in the higher NIR wavelength range, in which the EQE of the conventional CT-OPD is small, in comparison with a conventional CT-OPD, which has as photoactive layer a mixed layer of the same donor and acceptor compound with a concentration ratio optimized for the photoinduced excitation of an intermolecular CT state. For some wavelengths to be detected, an optoelectronic component according to the invention, in particular with a concentration ratio optimized in the above sense, can have an EQE of significantly more than 100% (e.g., 1000%).

In addition to the photoactive layer, an optoelectronic component according to the invention can have further layers which are also arranged between the two electrodes and/or between the mirror surfaces of the microcavity.

In principle, the wavelength to be detected of a CT-OPD can be varied by changing the optical path length between the mirror surfaces, wherein the variation need not take place via the thickness of the photoactive layer but can take place via an arrangement of at least one spacer layer, which is largely transparent at least for the wavelength to be detected, between the mirror surfaces. Embodiments of the optoelectronic component according to the invention can have such an arrangement of optical spacer layers.

In one embodiment of the optoelectronic component according to the invention, a spacer layer that is transparent at least for the wavelength to be detected is arranged between the second electrode and the photoactive mixed layer, so that the mixed layer is arranged closer to the first electrode, i.e., to the electrode injecting charge carriers, than to the second electrode. Advantageously, with the aid of this embodiment, the charge carrier injection from the first electrode into the photoactive layer can be further enhanced.

In a further embodiment of the optoelectronic component according to the invention, at least a first charge carrier blocking layer is arranged between the first electrode and the photoactive layer. Depending on the type of charge carrier to be blocked, the blocking layer may be an electron blocking layer (EBL) or a hole blocking layer (HBL). The first blocking layer may serve to attenuate, in the non-illuminated state of the optoelectronic component, the transport of charge carriers (main charge carriers) associated with the highly concentrated compound injected from the first electrode to the first electrode. For example, in the case of a photoactive layer with a low concentration of the acceptor compound according to the invention, an HBL can be arranged between the photoactive layer and the first electrode (cathode). Advantageously, the dark current of the device can be reduced by means of this embodiment. The thickness of the first blocking layer is to be selected in such a way, in particular so small, that an injection of the blocked charge carriers, e.g., in the case of an HBL of the holes, into the photoactive layer is not prevented.

It is clear to the person skilled in the art that the position of the energy levels forming in the layer stack is decisive for whether a layer effectively leads to the blocking or transport of a particular charge carrier type.

The first blocking layer for the charge carriers assigned to the high-concentration compound can act as a transport layer for the other charge carrier species assigned to the low-concentration compound. Depending on the charge carrier species to be transported, the transport layer may be an electron transport layer (ETL) or a hole transport layer (HTL). For example, an HBL can act as an ETL.

Such a transport layer disposed between the photoactive layer and the first electrode shall be designed such that there is no efficient extraction of transported charge carriers from the photoactive layer to the first electrode. For example, a HBL disposed between the cathode and the mixed layer acts as an ETL, wherein the ETL is designed such that the mobility of electrons in the ETL is low enough to ensure low extraction of electrons. This condition can be fulfilled, for example, by the ETL being undoped.

In a further embodiment of the optoelectronic component according to the invention, at least a second charge carrier blocking layer is arranged between the first electrode and the photoactive layer, which, in contrast to the first blocking layer, additionally attenuates the transport of the charge carriers associated with the low-concentration compound towards the first electrode in relation to an optoelectronic component according to the invention without a second blocking layer and thus leads to an enhancement of the photoinduced accumulation of the charge carriers associated with the low-concentration compound. The arrangement of a second blocking layer thus contributes to an amplification of the photomultiplication effect in the device.

If the low-concentration compound is the acceptor, i.e., if electrons are to be accumulated, the second blocking layer is an EBL. In the case of the donor as a low-concentration compound, the second blocking layer is an HBL. It is clear to the person skilled in the art that the material of the second blocking layer is to be selected in such a way that the energy levels, in the case of electrons to be blocked the LUMO, in the case of holes to be blocked the HOMO, in relation to the position of the energy levels of the photoactive layer cause a blocking of the desired charge carrier species.

The optoelectronic component according to the invention may have at least one first blocking layer, or at least one second blocking layer, or at least one first and at least one second blocking layer. In the latter case, the second blocking layer is expediently arranged on the photoactive layer and the first blocking layer is arranged on the first electrode.

In a further embodiment of the optoelectronic component according to the invention, at least one transport layer for the charge carriers injected from the first electrode and associated with the high-concentration compound is arranged between the second electrode and the photoactive layer, which transport layer can act as a blocking layer for the charge carriers associated with the low-concentration compound in order to largely prevent the transport of these charge carriers to the second electrode. For example, a HTL can be arranged between the photoactive layer and the anode, which acts as an EBL.

Furthermore, an optoelectronic component according to the invention may have optical input filters to obtain a narrowband output signal in the range of the wavelength to be detected.

The optoelectronic component according to the invention may be arranged on a substrate, which may be rigid, partially flexible, or flexible. In particular, it is useful to make the substrate transparent at least for the wavelength to be detected in order to be able to illuminate the optoelectronic component through the substrate. The optoelectronic component can have an encapsulation to reduce the effect of harmful environmental influences.

The invention also relates to a method for spectrally selective detection of electromagnetic radiation, which comprises at least the following method steps:
a. Providing an optoelectronic component according to the invention;
b. Illuminating the optoelectronic component with an incident wave of electromagnetic radiation having a wavelength to be detected and generating free charge carriers by direct excitation and dissociation of the intermolecular charge transfer state at an interface between donor compound and acceptor compound in the photoactive layer of the optoelectronic component;
c. Applying an electric voltage to the electrodes of the optoelectronic component, the electric voltage being directed such that the charge carriers associated with the low-concentration compound of its photoactive layer accumulate in a region of the photoactive layer facing the first electrode;
d. Accumulating charge carriers associated with the low-concentration compound in a region of the photoactive layer of the optoelectronic component facing the first electrode;
e. Injecting charge carriers associated with the high-concentration compound from the first electrode into the photoactive layer of the optoelectronic component;
f. Transporting the charge carriers associated with the high-concentration compound and the charge carriers of the same type generated by illumination to the second electrode of the optoelectronic device.

If the optoelectronic component according to the invention has a low concentration of the acceptor compound in at least a region of the photoactive layer facing the cathode, under illumination of the optoelectronic component and with a voltage applied to the electrodes in the reverse direction (positive pole at the cathode, negative pole at the anode), electrons accumulate in the region of the photoactive layer facing the cathode and, as a result, holes are injected from the cathode into the photoactive layer. The additional injected holes are transported to the anode with the photoinduced holes present in the photoactive layer after dissociation of the charge carrier pairs generated by direct excitation of the intermolecular CT state at an interface between donor compound and acceptor compound.

This explanation of the process according to the invention, which is given for the case of a low acceptor compound, can be readily transferred by the skilled person to an embodiment of the device according to the invention with a low concentration of the donor compound.

If the optoelectronic component according to the invention has at least one second blocking layer which is designed to block the non-main charge carriers associated with the low-concentration compound and is arranged between the photoactive layer and the first electrode, an accumulation of these charge carriers in process step c. additionally takes place at this blocking layer.

In the context of this description, the term “at least one” is used for the sake of brevity, which may mean: one, exactly one, several (e.g., exactly two, or more than two), many (e.g., exactly three or more than three), etc. Here, “several” or “many” need not necessarily mean that there are several or many identical elements, but several or many essentially functionally identical elements.

The invention is not limited to the embodiments shown and described, but also includes all embodiments having the same effect within the meaning of the invention. Furthermore, the invention is also not limited to the specifically described combinations of features, but may also be defined by any other combination of specific features of all the individual features disclosed, provided that the individual features are not mutually exclusive, or a specific combination of individual features is not explicitly excluded.

The invention will be explained in the following by examples of embodiments based on figures, without being limited thereto.

It is shown in:

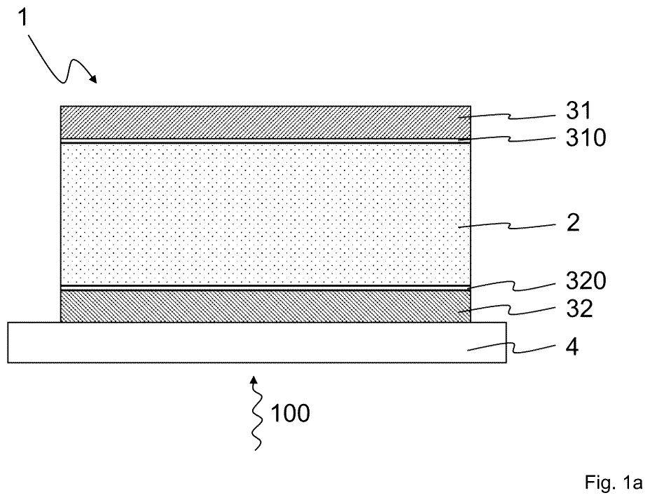

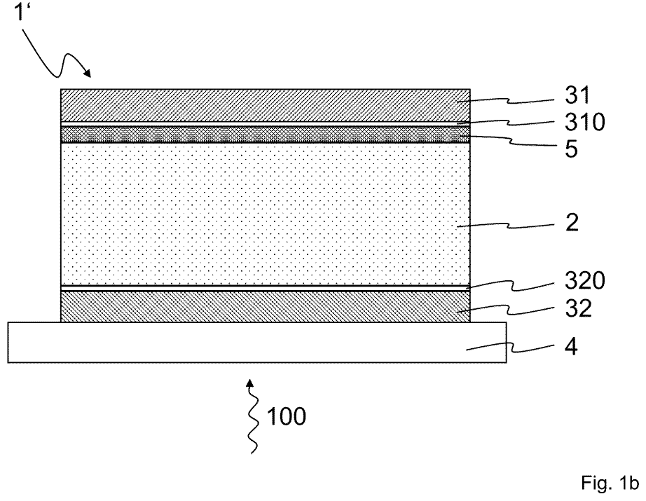

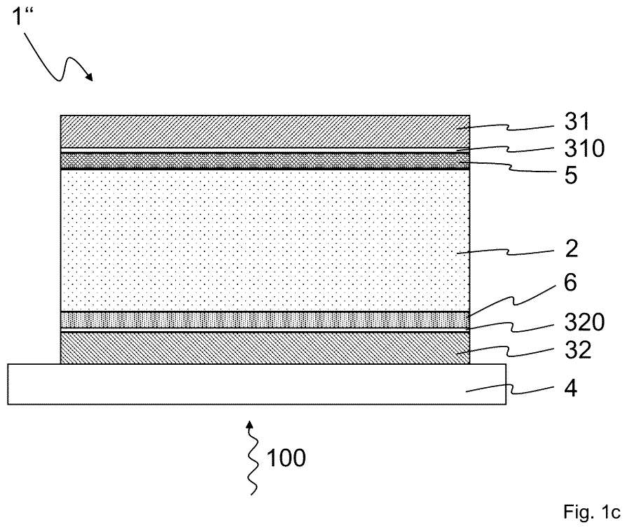

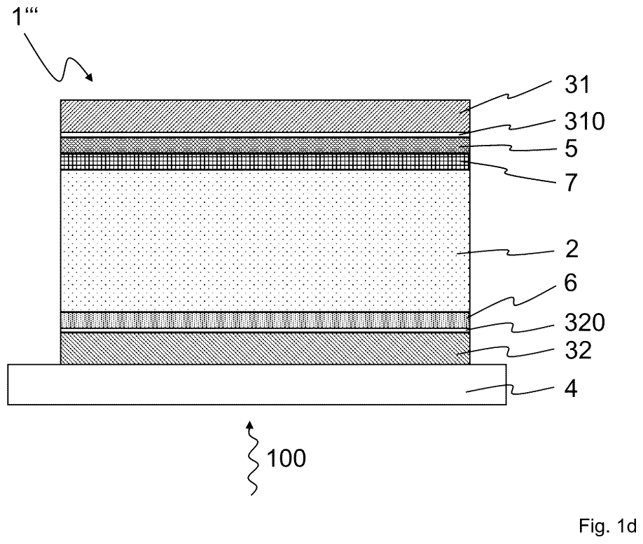

FIG. 1a the layered structure of an optoelectronic component according to the invention in a first embodiment;

FIG. 1b the layered structure of an optoelectronic component according to the invention in a second embodiment;

FIG. 1c the layered structure of an optoelectronic component according to the invention in a third embodiment;

FIG. 1d the layered structure of an optoelectronic component according to the invention in a fourth embodiment;

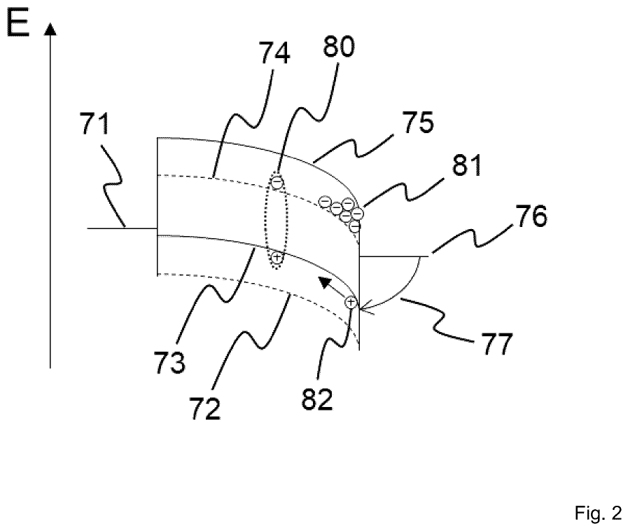

FIG. 2 a schematic energy diagram for the optoelectronic component of FIG. 1a according to the invention;

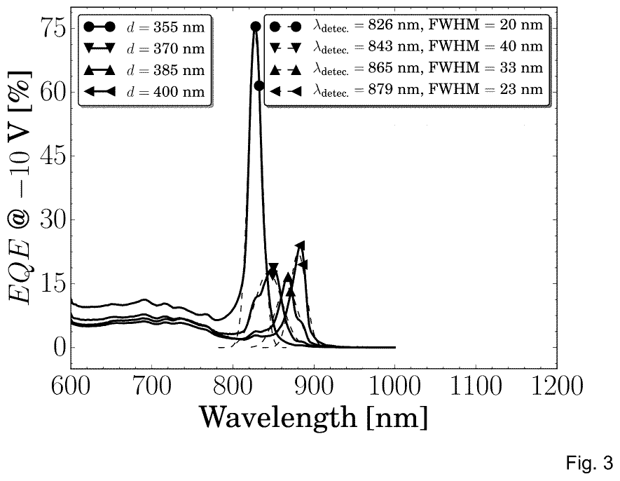

FIG. 3 the wavelength dependence of the EQE of an optoelectronic component according to the invention at different lengths L of the optical microcavity.

FIGS. 1a-d each show schematically the layer structure of an optoelectronic component 1, 1′, 1″,1′″ according to the invention. The optoelectronic component 1, 1′, 1″,1′″ has a photoactive layer 2 which is formed as a mixed layer of a donor compound, e.g., ZnPc, and an acceptor compound, e.g., C₆₀, the concentration, in terms of mass fraction, of C₆₀ in the mixed layer being very much lower than the concentration of ZnPc. For example, the mass fraction of C₆₀ in the mixed layer is 3%. The photoactive layer 2 is disposed between two spaced-apart opposing mirror surfaces 310, 320. The mirror surfaces 310, 320 are arranged between two electrodes 31, 32. The layer structure is applied to a substrate 4.

The first electrode, the top electrode, acts as cathode 31, the second electrode, the bottom electrode, as anode 32. A voltage can be applied between cathode 31 and anode 32 in the reverse direction, i.e., the positive pole is applied to cathode 31 and the negative pole to anode 32. The electrodes 31, 32 may be made of the same material or of different materials from each other. For example, the electrodes 31, 32 may be made of a metal, such as silver, aluminum, etc. A typical oxide material for the anode 32 may be ITO (indium tin oxide). The mirror surfaces 310, 320 may be mirror-like surfaces of the electrodes 31, 32 or layers separate from the electrodes 31, 32. The illumination system (not shown) for illuminating the optoelectronic component 1, 1′, 1″, 1′″ can be arranged on the substrate side, so that the illumination of the photoactive layer 2 takes place through the substrate 4, the bottom electrode 32 and the mirror surface 320 arranged on the bottom electrode (illumination direction 100). The aforementioned layers must therefore be at least partially transparent to the wavelength to be detected by means of the optoelectronic component 1, 1′, 1″, 1′″. The dependence of the wavelength to be detected on the thicknesses of the individual layers and the materials used can be evaluated via transfer matrix simulations.

The optoelectronic component 1 shown in FIG. 1a may have, for example, the following layer structure, the material and the thickness of the layer being indicated in brackets in each case:

Substrate 4 (glass, 1.1 mm)—partially transparent bottom electrode 32 with mirror-like surface 320 (Ag, 25 nm)—photoactive layer 2 (ZnPc:C₆₀ (3 wt %), 400 nm)—reflecting top electrode 31 with mirror-like surface 310 (Ag, 100 nm).

The EQE of the optoelectronic component 1 with the aforementioned layer structure shows a narrow peak (FWHM approx. 23 nm) at approx. 880 nm.

The optoelectronic component 1′ shown in FIG. 1b has, in addition to the layer structure of the optoelectronic component 1, a hole blocking layer (HBL) 5 arranged between the photoactive layer 2 and the top electrode/cathode 31 with mirror surface 310. The HBL can be, for example, a 10 nm thick layer consisting of HATNA-Cl₆, preferably undoped HATNA-Cl₆, in order to have only a weak electron-conducting effect.

The optoelectronic component 1″ shown in FIG. 1c has, in addition to the layer structure of the optoelectronic component 1′, a hole transport layer (HTL) 6, which is arranged between the photoactive layer 2 and the bottom electrode/anode 32 with mirror surface 320 and has an additional electron-blocking effect. The HTL may be, for example, a 10 nm thick doped layer made of MeO-TPD:F₆-TCNNQ.

In addition to the layer structure of the optoelectronic component 1″, the optoelectronic component 1′″ of FIG. 1d has an electron blocking layer (EBL) 7, which is arranged between the photoactive layer 2 and the HBL 5 and serves to accumulate electrons, i.e., the charge carriers associated with the low-concentration acceptor compound C₆₀, in the region of the photoactive layer 2 facing the top electrode/cathode 31. The EBL 6 can be, for example, a 10 nm thick layer of NTCDA or HAT(CN)₆.

FIG. 2 schematically shows an energy diagram for an optoelectronic component with a layer structure as in FIG. 1a under illumination with electromagnetic radiation and with a voltage applied to the electrodes of the optoelectronic component in the reverse direction. By illuminating the optoelectronic component with electromagnetic radiation, a CT state in the photoactive layer of the optoelectronic component can be excited by a photon the energy of which corresponds to, for example, the difference between the HOMO of the donor compound 73 and the LUMO of the acceptor compound 74 in the photoactive layer to form a charge carrier pair 80. After the dissociation of the charge carrier pair into free charge carriers, electrons 81 accumulate in the near-cathode region of the photoactive layer, since there are few percolation paths for electrons due to the low concentration of the acceptor compound in the photoactive layer. Due to the electric field created by the accumulation of electrons 81 in the near-cathode region of the photoactive layer, the depicted bending of the energy levels HOMO of the acceptor compound 72, HOMO of the donor compound 73, LUMO of the acceptor compound 74 and LUMO of the donor compound 75 occurs. The bending allows holes 82 from the cathode (Fermi level 76) to tunnel through the injection barrier (tunneling process illustrated by arrow 77) and be injected into the photoactive layer. Due to the high donor concentration in the photoactive layer, efficient transport of the injected holes together with the photoinduced holes 82 to the anode (Fermi level 71) occurs.

FIG. 3 shows the dependence of EQE on wavelength for four different optoelectronic components, with a reverse bias voltage of −10 V applied to the electrodes of each optoelectronic component. The optoelectronic components differ in the length L of the optical cavity. The EQE of an optoelectronic component according to the invention shows a narrow peak with a maximum at the wavelength λ_{detec}. to be detected, for which the resonance condition is fulfilled with respect to the selected length of its cavity. The full width at half-maximum (FWHM) of the peaks at the wavelengths to be detected shown is between 20 and 40 nm.

### Bezugszeichen

1, 1′, 1″,1′″ Optoelectronic component
100 Illumination direction
2 Photoactive layer
31 Top electrode, cathode
310 Mirror surface arranged at the top electrode
32 Bottom electrode, anode
320 Mirror surface arranged at the bottom electrode
4 Substrate
5 HBL
6 HTL
7 EBL
71 Fermi level of the bottom electrode/anode
72 HOMO of the acceptor compound
73 HOMO of the donor compound
74 LUMO of the acceptor compound
75 LUMO of the donor compound
76 Fermi level of the top electrode/cathode
77 Arrow to show the injection of holes from the cathode into the photoactive layer
80 Pair of charge carriers
81 Electron
82 Hole injected into the photoactive layer

1. An optoelectronic component (1, 1′, 1″, 1′″) for spectrally selective detection of electromagnetic radiation, comprising
a first (31) and a second electrode (32) which are spaced apart from one another and to which an electrical voltage can be applied,
a photoactive layer (2) comprising a mixed layer containing a donor compound and an acceptor compound, the energy equivalent of a wavelength of electromagnetic radiation to be detected corresponding to an energy to be expended to directly excite the intermolecular charge transfer state at an interface between the donor compound and the acceptor compound, the photoactive layer (2) being disposed in
an optical microcavity arranged between the first (31) and second electrodes (32) and constituted of two spaced-apart mirror surfaces (310, 320), the spacing of the mirror surfaces (310, 320) from each other being such that a standing wave is generated in the microcavity for an incident wave of electromagnetic radiation having the wavelength to be detected,
wherein the concentration of the donor compound at least in a region of the photoactive layer (2) facing the first electrode (31) or the concentration of the acceptor compound at least in a region of the photoactive layer (2) facing the first electrode (31) is so low that the low-concentration compound provides trap states for the charge carriers assigned to it, which cause a photoinduced accumulation of the charge carriers (81) associated with the low-concentration compound in a region of the photoactive layer (2) facing the first electrode (31), so that charge carriers (82) associated with the high-concentration compound are injected from the first electrode (31) into the photoactive layer, as a result of which this charge carrier species predominates in the component (1, 1′, 1″, 1′″).

2. The optoelectronic component (1, 1′, 1″, 1′″) according to claim 1, wherein the concentration of the donor compound throughout the photoactive layer (2) or the concentration of the acceptor compound throughout the photoactive layer (2) is so low that the low-concentration compound provides trap states for the charge carriers assigned to it, which cause a photoinduced accumulation of the charge carriers (81) associated with the low-concentration compound in a region of the photoactive layer (2) facing the first electrode (31), so that charge carriers (82) associated with the high-concentration compound are injected from the first electrode (31) into the photoactive layer, as a result of which this charge carrier species predominates in the component (1, 1′, 1″, 1′″).

3. The optoelectronic component according to claim 1, wherein the concentration of the low-concentration compound increases from the region of the photoactive layer (2) facing the first electrode (31) at least to a region of the photoactive layer (2) different from the region facing the first electrode in the direction of the second electrode (32), wherein the increase in concentration can be continuous or discontinuous.

4. The optoelectronic component (1, 1′, 1″, 1′″) according to claim 1, wherein the concentration of the donor compound at least in the region of the photoactive layer (2) facing the first electrode (31) or the concentration of the acceptor compound at least in the region of the photoactive layer (2) facing the first electrode (31) is between 1 and 10% by weight.

5. The optoelectronic component according to claim 1, wherein an optically transparent spacer layer is arranged between the second electrode (32) and the photoactive layer (2), so that the photoactive layer (2) is arranged closer to the first electrode (31) than to the second electrode (32).

6. The optoelectronic component (1′, 1″, 1′″) according to claim 1, wherein at least a first blocking layer (5) is arranged between the first electrode (31) and the photoactive layer (2), the first blocking layer (5) attenuating, in the non-illuminated state of the optoelectronic component (1′, 1″, 1′″), the transport to the first electrode (31) of the charge carriers (82) injected from the first electrode (31) and associated with the high-concentration compound of the photoactive layer (2).

7. The optoelectronic component (1′) according to claim 1, wherein at least one second blocking layer (7) is arranged between the first electrode (31) and the photoactive layer (2), the second blocking layer (7) at least attenuating the transport of the charge carriers (81) associated with the low-concentration compound of the photoactive layer (2) to the first electrode (31) and bringing about the photoinduced accumulation of the charge carriers (81) associated with the low-concentration compound at the second blocking layer (7).

8. The optoelectronic component (1″,1′″) according to claim 1, wherein at least one transport layer (6) for the charge carriers (82) injected by the first electrode (31) and assigned to the high-concentration compound of the photoactive layer (2) is arranged between the second electrode (32) and the photoactive layer (2), which transport layer (6) acts as a blocking layer for the charge carriers (81) assigned to the low-concentration compound of the photoactive layer.

9. A method for spectrally selective detection of electromagnetic radiation, comprising at least the following method steps:
a. providing an optoelectronic component (1, 1′, 1″, l′″) according to claim 1;
b. illuminating the optoelectronic component (1, 1′, 1″, 1′″) with an incident wave of electromagnetic radiation having a wavelength to be detected and generating free charge carriers by directly exciting and dissociating the intermolecular charge transfer state at an interface between donor compound and acceptor compound in the photoactive layer (2) of the optoelectronic component (1, 1′, 1″, 1′″);
c. applying an electrical voltage to the electrodes (31, 32) of the optoelectronic component (1, 1′, 1″, 1′″), the electrical voltage being directed in such a way that the charge carriers (81) associated with the low-concentration compound accumulate in a region of the photoactive layer (2) facing the first electrode (31);
d. accumulating charge carriers (81) associated with the low-concentration compound of the photoactive layer (2) in a region of the photoactive layer (2) facing the first electrode (31) of the optoelectronic component (1, 1′, 1″, 1′″);
e. injecting charge carriers (82) associated with the high-concentration compound of the photoactive layer (2) from the first electrode (31) into the photoactive layer (2) of the optoelectronic component (1, 1′, 1″, l′″);
f. transporting the injected charge carriers (82) associated with the high-concentration compound of the photoactive layer and the charge carriers of the same type generated by illumination to the second electrode (32) of the optoelectronic component (1, 1′, 1″, 1′″) and generating a readable electrical signal.

10. The optoelectronic component (1, 1′, 1″, 1′″) according to claim 1, wherein the concentration of the donor compound at least in the region of the photoactive layer (2) facing the first electrode (31) or the concentration of the acceptor compound at least in the region of the photoactive layer (2) facing the first electrode (31) is between 1 and 5% by weight.

11. The optoelectronic component (1, 1′, 1″, 1′″) according to claim 1, wherein the concentration of the donor compound at least in the region of the photoactive layer (2) facing the first electrode (31) or the concentration of the acceptor compound at least in the region of the photoactive layer (2) facing the first electrode (31) is between 1 and 4% by weight.

12. The optoelectronic component (1, 1′, 1″, 1′″) according to claim 1, wherein the concentration of the donor compound at least in the region of the photoactive layer (2) facing the first electrode (31) or the concentration of the acceptor compound at least in the region of the photoactive layer (2) facing the first electrode (31) is between 1 and 3% by weight
